(19) United States
(12) Patent Application Publication
(10) Pub. No.: US 2025/0248172 A1
(43) Pub. Date: Jul. 31, 2025

(54) GROUP III NITRIDE SEMICONDUCTOR AND PRODUCTION METHOD THEREFOR

(71) Applicant: TOYODA GOSEI CO., LTD., Kiyosu-shi (JP)

(72) Inventors: Koji OKUNO, Kiyosu-shi (JP); Yoshiki SAITO, Kiyosu-shi (JP); Tetsuya TAKEUCHI, Nagoya-shi (JP); Satoshi KAMIYAMA, Nagoya-shi (JP); Motoaki IWAYA, Nagoya-shi (JP); Hisanori ISHIGURO, Nagoya-shi (JP); Maho FUJITA, Nagoya-shi (JP)

(21) Appl. No.: 19/028,741

(22) Filed: Jan. 17, 2025

(30) Foreign Application Priority Data
Jan. 25, 2024 (JP) 2024-009500

(51) Int. Cl. H10H 20/01; C30B 33/12; H10H 20/825

(52) U.S. Cl. CPC H10H 20/01335; C30B 33/12; H10H 20/825

(57) ABSTRACT

A method for producing a Group III nitride semiconductor includes: forming a crystal nucleus layer by generating nuclei of AlGaN or AlN over a substrate containing sapphire; forming a semiconductor layer containing a Group III nitride semiconductor over the crystal nucleus layer; forming a void by irradiating a back surface side of the substrate with laser light to pass the laser light through the substrate and cause the crystal nucleus layer to absorb the laser light to thereby generate heat in the crystal nucleus layer, and by conducting the heat from the crystal nucleus layer to the substrate to decompose a region of the substrate near an interface with the crystal nucleus layer; and separating the substrate from the crystal nucleus layer at a position of the void.

### CROSS-REFERENCE TO RELATED APPLICATION

This application is based on and claims priority under 35 USC 119 from Japanese Patent Application No. 2024-009500 filed on Jan. 25, 2024.

### TECHNICAL FIELD

The present invention relates to a Group III nitride semiconductor and a production method therefor.

### BACKGROUND ART

Laser lift-off (LLO) is known as a technique of separating a substrate from a semiconductor layer formed on the substrate. The laser lift-off is a method of separating the substrate from the semiconductor layer by irradiating a back surface side of the substrate with laser light to decompose the semiconductor layer at an interface between the substrate and the semiconductor layer, after the semiconductor layer is formed on the substrate.

JP2018-61049A discloses that in a light emitting element in which an n-type layer, a light emitting layer, and a p-type layer are formed on a growth substrate made of sapphire via a buffer layer made of AlN, a back surface side of the growth substrate is irradiated with a lase to decompose the buffer layer and separate the growth substrate.

### SUMMARY OF INVENTION

The laser lift-off is an established technique and has been commercialized when the substrate is made of sapphire and the semiconductor layer is made of GaN. On the other hand, since AlN has a bond energy larger than that of GaN, an Al—N bond cannot be easily broken. Therefore, the laser lift-off technique has not been established when the substrate is made of sapphire and the semiconductor layer is made of AlN. In JP2018-61049A, the growth substrate is separated by thermally decomposing the buffer layer made of AlN, but in order to thermally decompose AlN, a laser output needs to be very high, which is difficult to achieve.

The present invention has been made in view of such a background, and an object thereof is to provide a method for producing a Group III nitride semiconductor capable of separating a substrate made of sapphire from a laminate including the substrate and a semiconductor layer made of a Group III nitride semiconductor.

An aspect of the present invention relates to a method for producing a Group III nitride semiconductor including:
a crystal nucleus layer forming step of forming a crystal nucleus layer by generating a nucleus of AlGaN or AlN on a substrate made of sapphire;
a semiconductor layer forming step of forming a semiconductor layer made of a Group III nitride semiconductor on the crystal nucleus layer;
a void forming step of forming a void by irradiating a back surface side of the substrate with laser light to pass the laser light through the substrate and cause the crystal nucleus layer to absorb the laser light to thereby generate heat in the crystal nucleus layer, and by conducting the heat from the crystal nucleus layer to the substrate to decompose a region of the substrate near an interface with the crystal nucleus layer; and
a substrate separation step of separating the substrate from the crystal nucleus layer at a position of the void.

Another aspect of the present invention relates to a Group III nitride semiconductor including:
a crystal nucleus layer, which is a layer in which a nucleus of AlGaN or AlN is generated and grown;
a semiconductor layer made of a Group III nitride semiconductor, which is formed on one surface of the crystal nucleus layer; and
a plurality of protrusion portions made of sapphire, which are formed on the other surface of the crystal nucleus layer, in which
the surface of the crystal nucleus layer is exposed between adjacent protrusion portions.

In the above aspect, the void is formed in the substrate made of sapphire by using the laser light, and there is no need to form the void in the crystal nucleus layer. Therefore, an output of the laser light can be reduced.

As above, according to the above aspects, it is possible to provide a method for producing a Group III nitride semiconductor capable of separating a substrate made of sapphire from a laminate including the substrate and a semiconductor layer made of a Group III nitride semiconductor.

### BRIEF DESCRIPTION OF DRAWINGS

FIG. 1 is a cross-sectional view showing a configuration of a light emitting element according to a first embodiment, and is a view showing a cross section perpendicular to a main surface of a substrate.

FIG. 2 shows diagrams each schematically showing a layer configuration at each growth stage up to formation of a two-dimensional growth layer.

FIG. 3 shows schematic diagrams showing warpage of the substrate at each growth stage.

FIG. 4 is a graph showing a change in temperature and pressure over time during formation of an AlN layer.

FIG. 5 is a diagram showing a process for producing the light emitting element according to the first embodiment.

FIG. 6 is a diagram showing the process for producing the light emitting element according to the first embodiment.

FIG. 7 is a diagram showing the process for producing the light emitting element according to the first embodiment.

FIG. 8 is a diagram showing the process for producing the light emitting element according to the first embodiment.

FIG. 9 is a diagram showing the process for producing the light emitting element according to the first embodiment.

FIG. 10 is a photograph showing a sample viewed from a substrate side.

FIG. 11 shows cross-sectional SEM images of the sample.

FIG. 12 is a cross-sectional SEM image of a sample.

FIG. 13 is a diagram showing element mapping of Al, Ga, O, and N.

FIG. 14 is a graph showing a relationship between an Al composition in a crystal nucleus layer, an energy density of laser light, and separation of the substrate.

FIG. 15 is a cross-sectional view showing a configuration of a light emitting element according to a modification of the first embodiment, and is a view showing a cross section perpendicular to a main surface of a substrate.

### DETAILED DESCRIPTION OF THE INVENTION

A method for producing a Group III nitride semiconductor includes: a crystal nucleus layer forming step of forming a crystal nucleus layer by generating a nucleus of AlGaN or AlN on a substrate made of sapphire; a semiconductor layer forming step of forming a semiconductor layer made of a Group III nitride semiconductor on the crystal nucleus layer; a void forming step of forming a void by irradiating a back surface side of the substrate with laser light to pass the laser light through the substrate and cause the crystal nucleus layer to absorb the laser light to thereby generate heat in the crystal nucleus layer, and by conducting the heat from the crystal nucleus layer to the substrate to decompose a region of the substrate near an interface with the crystal nucleus layer; and a substrate separation step of separating the substrate from the crystal nucleus layer at a position of the void.

In the above method for producing a Group III nitride semiconductor, in the substrate separation step, a protrusion portion may be formed on a surface of the crystal nucleus layer facing the substrate by a part of the substrate remaining on the crystal nucleus layer.

In the above method for producing a Group III nitride semiconductor, when an Al composition in the crystal nucleus layer (a ratio of number of moles of Al in the crystal nucleus layer to a total number of moles of the crystal nucleus layer) is x, and an energy density (J/cm²) of the laser light is y, the energy density y of the laser light may satisfy y≥3x−1.4.

In the above method for producing a Group III nitride semiconductor, the laser light may have an energy density of 1.6 J/cm² or more.

In the above method for producing a Group III nitride semiconductor, the energy density of the laser light may be 5 J/cm² or less.

In the above method for producing a Group III nitride semiconductor, the nucleus of the crystal nucleus layer may be AlGaN or AlN having an Al composition of 50% or more.

In the above method for producing a Group III nitride semiconductor, the semiconductor layer may have a low-temperature three-dimensional growth layer formed on the crystal nucleus layer, and a high-temperature three-dimensional growth layer formed on the low-temperature three-dimensional growth layer, and the semiconductor layer forming step may include a low-temperature three-dimensional growth layer forming step of forming the low-temperature three-dimensional growth layer by growing AlGaN or AlN from the nucleus at a temperature lower than a temperature in the crystal nucleus layer forming step and combining crystals from adjacent nuclei, and a high-temperature three-dimensional growth layer forming step of forming the high-temperature three-dimensional growth layer by growing AlGaN or AlN from the low-temperature three-dimensional growth layer at a temperature higher than the temperature in the low-temperature three-dimensional growth layer forming step and equal to or lower than the temperature in the crystal nucleus layer forming step.

In the above method for producing a Group III nitride semiconductor, the temperature in the crystal nucleus layer forming step may be 1100° C. or higher and 1200° C. or lower, the temperature in the low-temperature three-dimensional growth layer forming step may be 900° C. or higher and 1100° C. or lower, and the temperature in the high-temperature three-dimensional growth layer forming step may be 1050° C. or higher and 1200° C. or lower.

In the above method for producing a Group III nitride semiconductor, the semiconductor layer may have a low-temperature three-dimensional growth layer formed on the crystal nucleus layer, and a high-temperature three-dimensional growth layer formed on the low-temperature three-dimensional growth layer, and the semiconductor layer forming step may include a low-temperature three-dimensional growth layer forming step of forming the low-temperature three-dimensional growth layer by growing AlGaN or AlN from the nucleus at a growth rate smaller than a growth rate of the crystal nucleus layer and combining crystals from adjacent nuclei, and a high-temperature three-dimensional growth layer forming step of forming the high-temperature three-dimensional growth layer by growing AlGaN or AlN from the low-temperature three-dimensional growth layer at a growth rate larger than the growth rate of the low-temperature three-dimensional growth layer and equal to or smaller than the growth rate of the crystal nucleus layer.

In the above method for producing a Group III nitride semiconductor, the growth rate of the crystal nucleus layer may be 5 nm/min or more and 100 nm/min or less, the growth rate of the low-temperature three-dimensional growth layer may be 2 nm/min or more and 20 nm/min or less, and the growth rate of the high-temperature three-dimensional growth layer may be 5 nm/min or more and 50 nm/min or less.

The above method for producing a Group III nitride semiconductor may further include: an unevenness forming step of forming unevenness having a depth from the crystal nucleus layer to the semiconductor layer by etching the crystal nucleus layer exposed by separation of the substrate, after the substrate separation step.

The above method for producing a Group III nitride semiconductor may further include: a thermal cleaning step of subjecting the substrate to a heat treatment under a hydrogen-dominated atmosphere at a temperature higher than a temperature in the crystal nucleus layer forming step, before the crystal nucleus layer forming step.

A Group III nitride semiconductor includes: a crystal nucleus layer, which is a layer in which a nucleus of AlGaN or AlN is generated and grown; a semiconductor layer made of a Group III nitride semiconductor, which is formed on one surface of the crystal nucleus layer; and a plurality of protrusion portions made of sapphire, which are formed on the other surface of the crystal nucleus layer, in which the surface of the crystal nucleus layer is exposed between adjacent protrusion portions.

In the above Group III nitride semiconductor, the protrusion portion may have a height of 0.01 μm to 1 μm, the protrusion portion may have a width of 0.01 μm to 1 μm, and the adjacent protrusion portions may have a center-to-center distance of 0.02 μm to 5 μm.

In the above Group III nitride semiconductor, the semiconductor layer may have a three-dimensional growth layer formed on the crystal nucleus layer, which is a layer in which AlGaN or AlN is grown from the nucleus and crystals from adjacent nuclei are combined, and a two-dimensional growth layer formed on the three-dimensional growth layer, which is a layer in which AlGaN or Ga-doped AlN is grown from the three-dimensional growth layer.

### First Embodiment

### 1. Configuration of Light Emitting Element

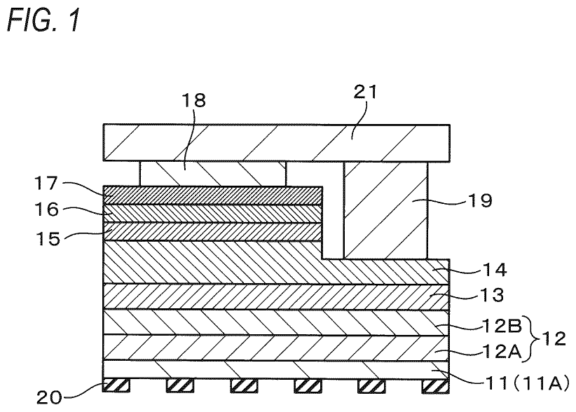

FIG. 1 is a cross-sectional view showing a configuration of a light emitting element according to a first embodiment, and is a view showing a cross section perpendicular to a main surface of a substrate. As shown in FIG. 1, the light emitting element according to the first embodiment includes a crystal nucleus layer 11, a three-dimensional growth layer 12, a two-dimensional growth layer 13, an n-type layer 14, an active layer 15, an electron blocking layer 16, a p-type layer 17, a p-side electrode 18, an n-side electrode 19, and a protrusion portion 20, and the p-side electrode 18 and the n-side electrode 19 are bonded to a support substrate 21. The light emitting element according to the first embodiment has an emission wavelength in a UVC band.

The crystal nucleus layer 11 is located on a substrate 10. The crystal nucleus layer 11 is a layer in which a nucleus 11A made of AlN is generated on a surface of the substrate 10 and grown three-dimensionally.

The crystal nucleus layer 11 preferably has a thickness (a height of the nucleus 11A) of 1 nm to 200 nm. When the thickness of the crystal nucleus layer 11 is within this range, the nucleus 11A is sufficiently large, and a quality of a crystal layer formed after the nucleus 11A can be improved. The thickness of the crystal nucleus layer 11 is more preferably 2 nm to 40 nm, and still more preferably 3 nm to 30 nm. Since the nucleus 11A is sufficiently large, the nucleus 11A has a small density. For example, when the thickness of the crystal nucleus layer 11 is in the range of 5 nm to 100 nm, the density of the nucleus 11A is preferably 3×10¹¹/cm⁻² or less.

The nucleus 11A preferably has a size (average diameter in a plan view) of 20 nm to 50 nm. Here, the diameter is a diameter when the nucleus 11A is converted into a circle of the same area. It is the size of the nucleus 11A when the thickness of the crystal nucleus layer 11 is 5 nm to 100 nm. When the size of the nucleus 11A is within this range, a tensile stress can be sufficiently reduced. In addition, a variation in size of the nucleus 11A (a difference between a maximum diameter and the average diameter, and a difference between the average diameter and a minimum diameter) is preferably 10 nm or less.

It is important that the nucleus 11A is large. When the crystal nuclei are combined to form a flat film, the tensile stress is generated on the surface. Therefore, when the nucleus size is small and the density is large, the stress generated on the surface of the flat film obtained by combining the nuclei is also increased. Therefore, the nucleus density needs to be reduced. Therefore, it is effective to increase the nucleus size.

A small nucleus density has another advantage. Threading dislocations are formed at combining surfaces where the nuclei 11A are combined. A small nucleus density also reduces the amount of the combining surfaces where the nuclei 11A are combined. Therefore, when the nucleus density is reduced, the formation of threading dislocations can be reduced, and a high-quality crystal film can be formed.

The three-dimensional growth layer 12 is located on the crystal nucleus layer 11. The three-dimensional growth layer 12 is made of AlN. The three-dimensional growth layer 12 is a layer in which the nucleus 11A is three-dimensionally grown to combine with adjacent nuclei 11A, and AlN after combination is further grown three-dimensionally. The three-dimensional growth layer 12 is a laminate including a low-temperature three-dimensional growth layer 12A and a high-temperature three-dimensional growth layer 12B. The high-temperature three-dimensional growth layer 12B is a layer grown at a temperature higher than that of the low-temperature three-dimensional growth layer 12A. By allowing the nuclei 11A to combine three-dimensionally rather than growing into a two-dimensional flat film at a time, the stress generated on the surface can be relaxed.

In a surface of the low-temperature three-dimensional growth layer 12A, a proportion of a flat crystal plane parallel to a main surface of the substrate 10 is preferably smaller than a proportion of an obliquely inclined crystal plane. The obliquely inclined plane may be formed by low-order or high-order facets. For example, a {10-11} plane and a {11-22} plane.

The low-temperature three-dimensional growth layer 12A preferably has a thickness of 100 nm to 500 nm. Within this range, the nuclei 11A can be sufficiently combined to reduce a dislocation density. In addition, the low-temperature three-dimensional growth layer 12A has a surface roughness RMS of, for example, 10 nm to 100 nm. The thickness of the low-temperature three-dimensional growth layer 12A is more preferably 250 nm to 400 nm, and still more preferably 250 nm to 350 nm.

In a surface of the high-temperature three-dimensional growth layer 12B, the proportion of the flat crystal plane parallel to the main surface of the substrate 10 is preferably larger than the proportion of the obliquely inclined crystal plane. That is, the high-temperature three-dimensional growth layer 12B is a flatter film than the low-temperature three-dimensional growth layer 12A.

The high-temperature three-dimensional growth layer 12B has a thickness of 750 nm to 2000 nm. With such a thickness, the nucleus 11A and the low-temperature three-dimensional growth layer 12A can be combined sufficiently without any gaps, and the dislocation density can be reduced. The thickness of the high-temperature three-dimensional growth layer 12B is more preferably 1000 nm to 1750 nm, and still more preferably 1250 nm to 1500 nm.

Note that, the crystal nucleus layer 11 and the three-dimensional growth layer 12 may have voids in crystals. The voids are regions not to be filled by the growth of the nucleus 11A, and are spaces in the crystal filled with a carrier gas. The voids can also relax a residual stress in the film and prevent the generation of cracks.

The two-dimensional growth layer 13 is located on the three-dimensional growth layer 12. The two-dimensional growth layer 13 is a layer in which AlN is grown while supplying Ga. The two-dimensional growth layer 13 is made of AlN containing Ga or AlGaN. Ga is supplied as a surfactant to promote lateral growth during AlN film formation. In order to exhibit the surfactant effect, a molar ratio of Ga to Al in the formed AlN film needs to be larger than 0. With the surfactant effect, a surface of the two-dimensional growth layer 13 is a two-dimensionally flat surface without unevenness due to pits or crystal facets.

AlN containing Ga is in a state where Ga is dissolved in AlN, and is AlN containing Ga to such an extent that it does not form a mixed crystal of GaN and AlN. For example, the molar ratio of Ga to Al in the two-dimensional growth layer 13 is larger than 0% and 0.5% or less.

The surfactant effect of Ga is exhibited even when a content of Ga in AlN is increased to a level at which a mixed crystal of AlN and GaN (AlGaN) is formed. The level at which a mixed crystal is formed refers to a case where the molar ratio of Ga to Al is larger than 0.5%. On the other hand, when a Ga composition in AlGaN is too high, there is a high possibility that ultraviolet light from the active layer 15 is absorbed. Therefore, when the two-dimensional growth layer 13 is made of AlGaN, the Ga composition is preferably larger than 0.5% and 10% or less.

A Ga supply amount in the two-dimensional growth layer 13 may change in a thickness direction, and may increase continuously or stepwise with an increasing distance from the substrate 10. It is thought that a region on a back surface side of the two-dimensional growth layer 13 (the three-dimensional growth layer 12 side) is in a state where Ga is dissolved in AlN, and a front surface side thereof is in a mixed crystal state of AlN and GaN (that is, Al₁₋ₓGaₓN). The Ga composition x in Al₁₋ₓGaₓN also changes in the thickness direction, and the Ga composition increases continuously or stepwise from 0 to a predetermined value with an increasing distance from the substrate 10. A maximum value of the Ga composition x (that is, the Ga composition x near the surface of the two-dimensional growth layer 13) is 0.01 to 0.1.

In this way, the surface vicinity of the two-dimensional growth layer 13 is not AlN but a mixed crystal of AlN and GaN. However, the Ga composition x is sufficiently low, and the mixed crystal can function equivalently to AlN as a base layer for a deep ultraviolet light emitting element. In addition, the two-dimensional growth layer 13 is flat, has few cracks, and has a small dislocation density. By continuously increasing the Ga ratio, a difference in lattice mismatch with the n-type layer 14 (n-type AlGaN layer) laminated thereon is reduced, which also contributes to improving a crystal quality of the n-type layer 14.

The two-dimensional growth layer 13 has a thickness of 750 nm to 2000 nm. With such a thickness, the surface of the two-dimensional growth layer 13 is sufficiently flattened. For example, the two-dimensional growth layer 13 can have a surface roughness RMS of 0.5 nm to 5 nm. The surface of the two-dimensional growth layer 13 may have step bunching. The thickness of the two-dimensional growth layer 13 is more preferably 1000 nm to 1750 nm, and still more preferably 1250 nm to 1500 nm.

Threading dislocation densities of the high-temperature three-dimensional growth layer 12B and the two-dimensional growth layer 13 are smaller than threading dislocation densities of the crystal nucleus layer 11 and the low-temperature three-dimensional growth layer 12A. The threading dislocation densities of the high-temperature three-dimensional growth layer 12B and the two-dimensional growth layer 13 are, for example, 5×10⁹ cm⁻² or less, and the threading dislocation densities of the crystal nucleus layer 11 and the low-temperature three-dimensional growth layer 12A are, for example, 1×10¹⁰ cm⁻² or more.

In addition, with regard to the dislocation in the two-dimensional growth layer 13, the dislocation density of dislocations having an edge dislocation component is larger than the dislocation density of dislocations having a screw dislocation component. For example, the dislocation density of dislocations having an edge dislocation component is larger by 10 times or more.

In an X-ray diffraction pattern of the two-dimensional growth layer 13, a full width at half maximum (FWHM) of a (002) diffraction line is, for example, 20 arcsec to 200 arcsec, and a full width at half maximum of a (102) diffraction line is, for example, 200 arcsec to 800 arcsec.

The n-type layer 14 is located on the two-dimensional growth layer 13. The n-type layer 14 is made of n-AlGaN and has a Ga composition higher than the Ga composition in the two-dimensional growth layer 13. An n-type impurity is Si, and a Si concentration is 5×10¹⁸/cm³ to 5×10¹⁹/cm³. The n-type layer 14 may include a plurality of layers.

The active layer 15 is located on the n-type layer 14. The active layer 15 has an MQW structure in which a well layer and a barrier layer are alternately and repeatedly laminated. The number of repetitions is, for example, 2 to 5. The well layer is made of AlGaN, and an Al composition thereof is set according to a desired emission wavelength. For example, the emission wavelength is set to a predetermined value in a range of 200 nm to 280 nm. The barrier layer is made of AlGaN having an Al composition higher than that of the well layer. AlGaInN having a band gap energy larger than that of the well layer may also be used. In addition, the active layer 15 may have an SQW structure.

The electron blocking layer 16 is located on the active layer 15. The electron blocking layer 16 is made of AlGaN or AlN having an Al composition higher than that of the barrier layer of the active layer 15. The electron blocking layer 16 may be doped with a p-type impurity. The doping method may be constant or modulated, or may be combined with undoped layers. The electron blocking layer 16 prevents electrons injected from the n-side electrode 19 from going beyond the active layer 15 and diffusing to a p-type layer 17 side.

The p-type layer 17 is located on the electron blocking layer 16. The p-type layer 17 is made of p-AlGaN. In the light emitting element according to the first embodiment, all semiconductor layers from the n-type layer 14 to the p-type layer 17 are made of AlGaN, and accordingly absorption of ultraviolet light emitted from the active layer 15 by the semiconductor layers is prevented. The p-type impurity is Mg. A Mg concentration is 1×10¹⁸/cm³ or more. The p-type layer 17 may include a plurality of layers having different Al compositions and Mg concentrations. In this case, the layer in contact with the p-side electrode 18 may be made of p-GaN to reduce contact resistance.

The lowest Al composition in the p-type layer 17 is preferably an Al composition having a band gap that does not absorb ultraviolet light emitted from the active layer 15. For example, when the Al composition in the well layer of the active layer 15 is 40%, the lowest Al composition in the p-type layer 17 is preferably 40% or more. However, since a high Al composition increases the contact resistance with the p-side electrode 18, a layer having an Al composition of 0% to 40% may be laminated as a contact layer in a small thickness range of 1 nm to 50 nm. The layer having an Al composition of 0% to 40% absorbs the ultraviolet light emitted from the active layer 15, but transmits it to some extent because it is thin. Therefore, a large decrease in external quantum efficiency of an LED can be avoided.

Further, layers having an Al composition in the range of 0% to 90% may be combined. In this case, the Al composition is preferably set to decrease continuously or stepwise from an active layer 15 side. A superlattice structure may be formed, and the average Al composition may be decreased stepwise.

A groove having a depth reaching the n-type layer 14 is provided in a partial region of a surface of the p-type layer 17. This groove is for exposing the n-type layer 14 so as to provide the n-side electrode 19 therein.

The p-side electrode 18 is provided on the p-type layer 17. The p-side electrode 18 is a reflective electrode that improves light extraction efficiency by reflecting the ultraviolet light emitted from the active layer 15 to a substrate 10 side. A material for the p-side electrode 18 is Ru, Rh, Ni/Au, Ni/Al, or the like.

The n-side electrode 19 is provided on the n-type layer 14 exposed at a bottom surface of the groove. A material for the n-side electrode 19 is Ti/Al, V/Al, or the like.

The protrusion portion 20 is located on a back surface of the crystal nucleus layer 11 (a surface on a low-temperature three-dimensional growth layer 12A side). The protrusion portion 20 is made of sapphire. As to be described later, the protrusion portion 20 is formed by, at the time of forming a void 22 in the substrate 10 made of sapphire and separating the substrate 10 from the crystal nucleus layer 11, a part of the substrate 10 remaining on the back surface of the crystal nucleus layer 11. A plurality of protrusion portions 20 are present at intervals. Between the protrusion portion 20 and the protrusion portion 20, the back surface of the flat crystal nucleus layer 11 may be exposed. The flat crystal nucleus layer 11 corresponds to a position of the void 22 to be described later. By providing the protrusion portion 20 in this manner, the ultraviolet light emitted from the active layer 15 is scattered, and thus the light extraction efficiency can be improved.

The protrusion portion 20 has a height of, for example, 0.01 μm to 1 μm, the protrusion portion 20 has a width of, for example, 0.01 μm to 1 μm, and adjacent protrusion portions 20 have a center-to-center distance of for example, 0.02 μm to 5 μm.

The support substrate 21 is a substrate bonded to the p-side electrode 18 and the n-side electrode 19. The support substrate 21 is provided with an electrode pattern (not shown). The support substrate 21 is for supporting a wafer during laser lift-off to be described later. The support substrate 21 is preferably made of a material having a high thermal conductivity, such as AlN.

### 2. Method for Producing Light Emitting Element

Next, a method for producing the light emitting element according to the first embodiment will be described. Note that, a Group III nitride semiconductor is formed using an MOCVD method, and as a raw material gas, for example, ammonia is used as a nitrogen raw material gas, trimethylgallium (TMGa) or triethylgallium (TEGa) is used as a Ga raw material gas, trimethylaluminum (TMAI) is used as a Al raw material gas, and hydrogen or nitrogen is used as a carrier gas.

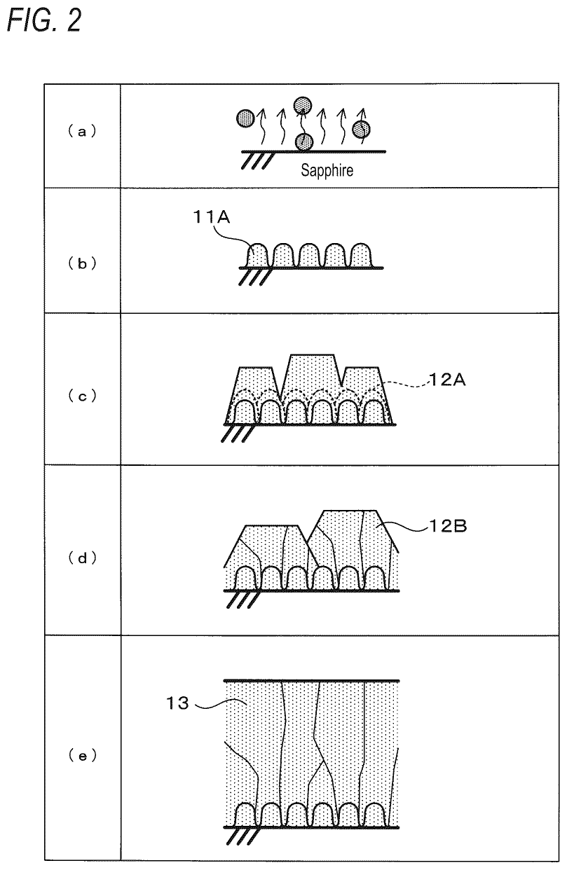

In the following description of the production method, reference will be made to FIG. 2 to FIG. 9 as appropriate. FIG. 2 shows diagrams each schematically showing a layer configuration in each growth stage up to formation of the two-dimensional growth layer 13.

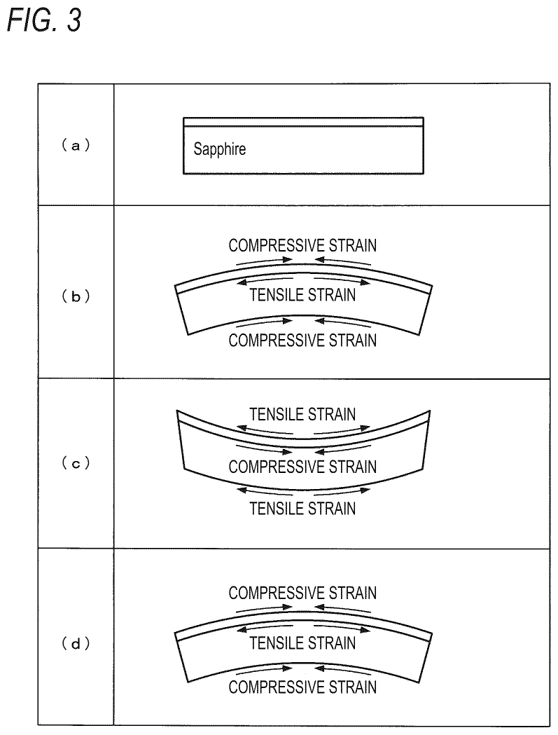

FIG. 3 shows diagrams schematically showing warpage of a wafer in each growth stage up to formation of the two-dimensional growth layer 13. Note that, the warpage of the wafer can also occur in bulk substrates on which nothing is grown. This is because the front surface of the substrate 10 is cooled by a carrier gas such as hydrogen, and therefore the temperature is strictly different from that of the back surface side of the substrate 10, and warpage may occur due to a difference in thermal expansion caused by this temperature difference. Therefore, the depiction of warpage in FIG. 3 is a conceptual representation of the behavior caused by a difference in lattice mismatch or a difference in thermal expansion coefficient when different materials are laminated, and there is a possibility that the warpage state may differ slightly from the actual state. Therefore, FIG. 3 conceptually shows a stress generated in the film by laminating layers and the resulting warpage.

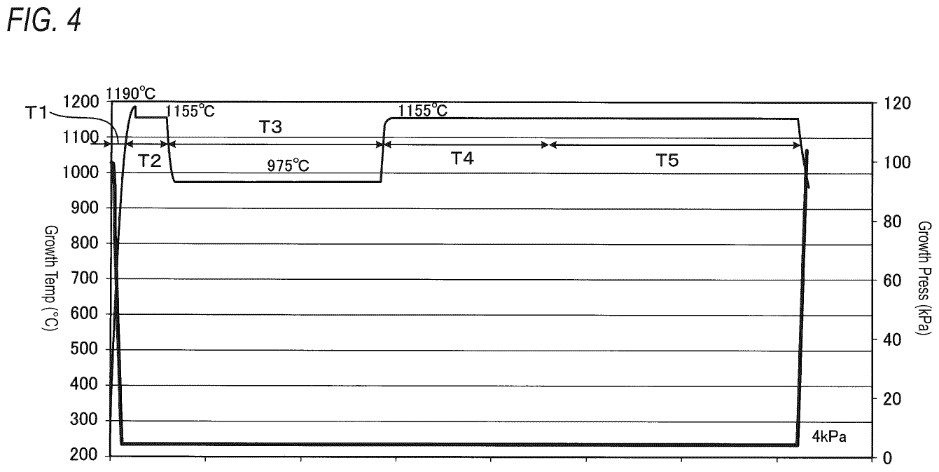

FIG. 4 is a graph showing a change in growth temperature and growth pressure over time up to formation of the two-dimensional growth layer 13.

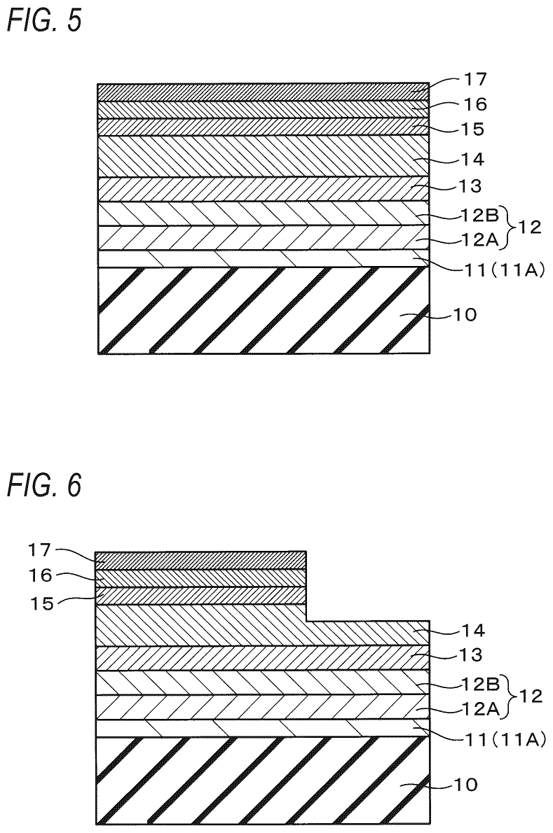

FIG. 5 to FIG. 9 show steps after the two-dimensional growth layer 13 is formed.

### 2-1. Thermal Cleaning

First, the substrate 10 made of sapphire having a c plane is prepared. A main surface of the sapphire may have an a-plane orientation. It has an off angle of 0.1 to 2 degrees in an m-axis direction or an a-axis direction.

Next, the substrate 10 is subjected to thermal cleaning under a hydrogen atmosphere at a temperature of 1150° C. to 1250° C. for 1 second to 15 minutes. Accordingly, the surface of the substrate 10 is subjected to impurity removal and flattening (see (a) in FIG. 2, (a) in FIG. 3, and FIG. 4). In FIG. 4, as an example, the growth temperature is 1190° C. and the pressure is 4 kPa. In FIG. 4, a period between this thermal cleaning and a nitriding treatment as a subsequent step is indicated as a period T1. It is thought that this thermal cleaning removes oxygen from the surface of the substrate 10, resulting in an Al-rich surface.

It is sufficient that the temperature in the thermal cleaning is higher than the temperature in the crystal nucleus layer forming step to be described later. The temperature in the thermal cleaning is in a range of more preferably 1170° C. to 1230° C., and still more preferably 1180° C. to 1210° C. The atmosphere may be a hydrogen-dominated atmosphere, for example, a mixed gas containing 80 vol % or more of hydrogen. The mixed gas is, for example, a mixed gas of hydrogen and nitrogen. The pressure may be a normal pressure, and a reduced pressure is preferred, for example, 1 kPa to 80 kPa, preferably 1 kPa to 50 kPa, and more preferably 1 kPa to 20 kPa. A flow rate of a hydrogen gas or a mixed gas of hydrogen and nitrogen on the substrate 10 may be 5 m/min (meters per minute) to 500 m/min, preferably 10 m/min to 300 m/min, and more preferably 15 m/min to 150 m/min.

### 2-2. Nitriding Treatment

Next, the Al-rich surface of the substrate 10 is nitrided by supplying ammonia at a temperature lower than that in the thermal cleaning. The pressure is the same as in the thermal cleaning. A flow rate of a carrier gas (hydrogen or a mixed gas of hydrogen and nitrogen) may be set to be same as or larger than the optimum range for the thermal cleaning. A flow rate of ammonia is the same as or smaller than that in the next step, and an ammonia partial pressure in the carrier gas, which is hydrogen or a mixed gas of hydrogen and nitrogen, is in a range of preferably 0.001 atm to 0.1 atm, and more preferably 0.01 atm to 0.05 atm. A nitriding treatment time is preferably 0.5 seconds to 10 minutes, and more preferably 60 seconds to 300 seconds. On the surface of the substrate 10, an AlN layer (not shown) of one to several monolayers is formed, which serves as a starting point for nucleation.

### 2-3. Step of Forming Crystal Nucleus Layer 11

Next, a nitrogen raw material gas and an Al raw material gas are supplied at a temperature same as that in the previous nitriding treatment step or at a temperature lower than that in the previous nitriding treatment step, the nucleus 11A of AlN is generated on the substrate 10, and the nucleus 11A is three-dimensionally grown to form the crystal nucleus layer 11 (see (b) in FIG. 2 and FIG. 4). In FIG. 4, the period of this step is shown as a period T2, and a case where the temperature is 1155° C. is shown as an example. The pressure is the same as in the previous step. In the conventional art, the nucleus 11A is generated and grown three-dimensionally at about 1000° C. In the first embodiment, by setting the temperature higher than this, the surface migration of the raw material atoms is enhanced, and the nucleus 11A is formed larger than that in the conventional art. Accordingly, the nucleus 11A made of AlN can have a high quality.

A difference in lattice mismatch between the nucleus 11A and the substrate 10 made of sapphire causes a compressive stress in the crystal nucleus layer 11. However, since the difference in lattice mismatch between the nucleus 11A and the substrate 10 is large, the stress is relaxed within a few nm, and a stress at an interface between the substrate 10 and the nucleus 11A is small.

The crystal nucleus layer 11 is preferably grown three-dimensionally to a thickness of 1 nm to 200 nm. The nucleus 11A can be sufficiently enlarged. In addition, the size and the density of the nucleus 11A is preferably within the above ranges.

A growth temperature of the crystal nucleus layer 11 is preferably 1100° C. to 1200° C. When the temperature is within this range, the nucleus 11A can be sufficiently enlarged. This is because the surface migration of the raw material atoms can be enhanced. The growth temperature is more preferably 1125° C. to 1190° C., and still more preferably 1150° C. to 1180° C. The temperature may be the same as that in the previous nitriding treatment step. When the nucleus 11A is enlarged, the nucleus density is reduced. Therefore, the number of interfaces between the nuclei 11A is also reduced. There is a possibility that the tensile stress is generated in the film when the nuclei 11A are combined to be flat, but by reducing the nucleus density as described above, the stress generated after the nuclei 11A are combined can be reduced.

The growth temperature of the crystal nucleus layer 11 may be changed stepwise or continuously. In this case, the average growth temperature is sufficiently 1100° C. to 1200° C.

A growth rate is preferably 5 nm/min to 100 nm/min. When the growth rate is large, the diameter of the nucleus 11A can be increased. The growth rate is more preferably 10 nm/min to 70 nm/min, and still more preferably 20 nm/min to 50 nm/min.

A V/III ratio is preferably 5 to 500. When the V/III ratio is within such a range, the growth rate can be controlled within the above range. The V/III ratio is more preferably 5 to 400, and still more preferably 5 to 300.

Note that, there is a possibility that AlN having a −c plane is formed on the substrate 10 subjected to the nitriding treatment, but can be made into one having a +c plane by adjusting growth conditions of the nucleus 11A, such as a small V/III ratio and a large growth rate. Generally, a crystal layer having a +c plane is preferred, and even when the crystal nucleus layer 11 contains a mixture of +c and −c, the proportion of −c is small, and +c is dominant during the growth process, so that the final crystal layer has a surface having only a +c plane.

### 2-4. Step of Forming Low-Temperature Three-Dimensional Growth Layer 12A

After the crystal nucleus layer 11 has grown to a predetermined thickness, the growth temperature is made lower than that in the step of forming the crystal nucleus layer 11 (period T2). Accordingly, the nucleus 11A of the crystal nucleus layer 11 is three-dimensionally grown, and adjacent nuclei 11A are combined to form the low-temperature three-dimensional growth layer 12A (see (c) in FIG. 2 and FIG. 4). In FIG. 4, the period of this step is shown as a period T3, and a case where the temperature is 975° C. is shown as an example. The pressure is the same as in the previous step. When the nuclei 11A are combined, it is possible to reduce the threading dislocations and to form a high-quality low-temperature three-dimensional growth layer 12A.

Here, since the temperature is lower than the temperature for forming the crystal nucleus layer 11, a stress acting on layers up to the low-temperature three-dimensional growth layer 12A due to a difference in linear expansion coefficient with the substrate 10 becomes a compressive stress (see FIG. 3). Generally, cracks are generated in the growth layer when the tensile stress is applied. Since a compressive strain is generated in the layers up to the low-temperature three-dimensional growth layer 12A, cracks can be prevented.

When the temperature is lowered, the low-temperature three-dimensional growth layer 12A can be grown slowly, and the combination of the low-temperature three-dimensional growth layers 12A growing starting from the nucleus 11A can also proceed slowly. There is a possibility that the tensile stress is generated when the nucleus 11A are combined. However, since the low-temperature three-dimensional growth layer 12A is grown slowly as described above, it is possible to prevent cracks caused by the tensile stress generated when the low-temperature three-dimensional growth layers 12A on the nucleus 11A are combined to be a continuous film.

The low-temperature three-dimensional growth layer 12A is preferably grown to be thicker than the crystal nucleus layer 11, for example, to a thickness of 200 nm to 500 nm. When nucleus shapes are sufficiently combined to a film shape starting from the nuclei 11A, the threading dislocation density can be reduced. Further, the thicker the low-temperature three-dimensional growth layer 12A is, the more uneven the three-dimensional surface can be. Accordingly, lateral growth promoted in subsequent steps can bend the threading dislocation, and the number of threading dislocations propagating to the surface of the growth layer can be reduced. The thickness is more preferably 250 nm to 400 nm, and still more preferably 250 nm to 350 nm.

A growth temperature of the low-temperature three-dimensional growth layer 12A is preferably 900° C. to 1100° C. When the growth temperature is 900° C. or higher, impurities are less likely to enter the crystal, and light absorption can be reduced. The growth temperature is more preferably 950° C. to 1050° C., and still more preferably 975° C. to 1025° C.

The low-temperature three-dimensional growth layer 12A has a growth rate smaller than the growth rate of the crystal nucleus layer 11. When the growth rate is smaller and the combination slowly proceeds starting from the nucleus 11A, the dislocations can be effectively reduced. In addition, the formation of the tensile stress generated when the nuclei 11A are combined to cause flattening can be relaxed. A growth rate is preferably 2 nm/min to 20 nm/min. The growth rate is more preferably 2 nm/min to 15 nm/min, and still more preferably 2 nm/min to 10 nm/min.

In addition, the low-temperature three-dimensional growth layer 12A has a V/III ratio larger than the V/III ratio of the crystal nucleus layer 11, which is preferably 500 to 2000. The growth rate can be controlled within the above range. The V/III ratio is more preferably 750 to 1750, and still more preferably 1000 to 1500.

### 2-5. Step of Forming High-Temperature Three-Dimensional Growth Layer 12B

After the low-temperature three-dimensional growth layers 12A grown starting from the nuclei 11A are sufficiently combined and the low-temperature three-dimensional growth layer 12A has grown to a predetermined thickness, the high-temperature three-dimensional growth layer 12B is formed by further growing on the low-temperature three-dimensional growth layer 12A at a growth temperature higher than that in the step of forming the low-temperature three-dimensional growth layer 12A (period T3) and equal to or lower than the growth temperature in the step of forming the crystal nucleus layer 11 (see (d) in FIG. 2 and FIG. 4). In FIG. 4, the period of this step is shown as a period T4, and a case where the temperature is 1155° C. is shown as an example. The pressure is the same as in the previous step.

The high-temperature three-dimensional growth layer 12B is a layer grown to allow a smooth transition from three-dimensional growth of the low-temperature three-dimensional growth layer 12A to two-dimensional growth of the two-dimensional growth layer 13. The high-temperature three-dimensional growth layer 12B is obtained by three-dimensional growth in which lateral growth is faster than that of the low-temperature three-dimensional growth layer 12A. Since the high-temperature three-dimensional growth layer 12B has a growth temperature higher than that of the low-temperature three-dimensional growth layer 12A, the lateral growth is faster than that of the low-temperature three-dimensional growth layer 12A, and the crystals can be more effectively combined. As a result, by bending the threading dislocations laterally, the number of threading dislocations propagating to the surface direction can be reduced, and a crystal film having a small threading dislocation density is obtained.

Here, the high-temperature three-dimensional growth layer 12B is formed at a temperature higher than that of the low-temperature three-dimensional growth layer 12A, and a difference in linear expansion coefficient with the substrate 10 generates a tensile stress in the crystal layer up to the high-temperature three-dimensional growth layer 12B compared to the growth of the low-temperature three-dimensional growth layer 12A (see (c) in FIG. 3). Therefore, the high-temperature three-dimensional growth layer 12B is preferably grown not as a completely flat film but as a three-dimensional surface partially having pits or facets, so that the tensile stress generated on the surface is relaxed to allow growth.

The high-temperature three-dimensional growth layer 12B is preferably grown to be thicker than the low-temperature three-dimensional growth layer 12A, for example, to a thickness of 750 nm to 2000 nm. Within this range, the threading dislocation density can be further reduced by further promoting the crystal combination. The thickness is more preferably 1000 nm to 1750 nm, and still more preferably 1250 nm to 1500 nm.

The growth temperature of the high-temperature three-dimensional growth layer 12B is preferably 1050° C. to 1200° C. Within such a range, the growth mode can be efficiently converted from the three-dimensional growth to the two-dimensional growth. The growth temperature is more preferably 1075° C. to 1175° C., and still more preferably 1100° C. to 1150° C.

The high-temperature three-dimensional growth layer 12B has a growth rate larger than the growth rate of the low-temperature three-dimensional growth layer 12A and equal to or smaller than the growth rate of the crystal nucleus layer 11, which is preferably 5 nm/min to 50 nm/min. When the growth rate is within this range, the crystals are slowly combined, a change in tensile stress generated on the surface of the crystal layer is relaxed, so that the generation of cracks when the crystals are combined can be prevented. The growth rate is more preferably 10 nm/min to 40 nm/min, and still more preferably 15 nm/min to 30 nm/min.

The high-temperature three-dimensional growth layer 12B has a V/III ratio smaller than the V/III ratio of the low-temperature three-dimensional growth layer 12A and equal to or larger than the V/III ratio of the crystal nucleus layer 11, which is preferably 100 to 1000. The growth rate can be controlled within the above range. The V/III ratio is more preferably 150 to 700, and still more preferably 200 to 500.

### 2-6. Step of Forming Two-Dimensional Growth Layer 13

After the high-temperature three-dimensional growth layer 12B has grown to a predetermined thickness, the two-dimensional growth layer 13 made of AlN containing Ga or AlGaN is formed at a temperature same as or higher than that in the step of forming the high-temperature three-dimensional growth layer 12B (period T4) by supplying a Ga raw material gas in addition to the nitrogen raw material gas and the Al raw material gas (see (e) in FIG. 2 and FIG. 4). In FIG. 4, the period of this step is shown as a period T5. The pressure is the same as in the previous step.

When Ga is supplied during the growth of AlN, the growth mode of AlN is two-dimensional growth in which lateral growth is promoted with Ga atoms, which have surface migration higher than that of Al atoms. Therefore, the two-dimensional growth layer 13 allows the crystal to be flattened. The Ga supply amount is increased continuously and stepwise over time. Accordingly, when the lateral growth rate is slowly increased to relax the change in tensile stress generated when the crystals are combined, the generation of cracks in the two-dimensional growth layer 13 can be prevented.

The Ga supply amount is controlled based on a molar ratio of the Ga raw material gas to the Al raw material gas. The molar ratio of the Ga raw material gas to the Al raw material gas is preferably 0.05 to 0.5, more preferably 0.08 to 0.4, and still more preferably 0.1 to 0.3.

Although the ratio of the Ga raw material gas is very high, Ga is not actually incorporated into AlN at the above ratio. This is because the Ga atoms evaporate more easily than the Al atoms on the AlN surface, so that the amount of Ga atoms actually incorporated into the AlN crystal is only a few percent even when the molar ratio of the Ga raw material gas is 0.3. As the growth temperature increases, the Ga atoms evaporate preferentially, and therefore fewer Ga atoms are incorporated into the AlN crystal. Although it depends on conditions such as the growth temperature, a Ga solid phase ratio in Al₁₋ₓGaₓN grown in the above molar ratio range is x=about 0.01% to 0.1%.

By applying a continuous, stepwise gradient within the above molar ratio range, the Ga supply amount is increased in gradient over time. By supplying Ga, the two-dimensional growth layer 13 changes from AlN to a mixed crystal of AlN and GaN (Al₁₋ₓGaₓN). Here, the Ga composition is preferably 0.01 to 0.1.

The two-dimensional growth layer 13 is preferably grown to have a thickness equal to or larger than that of the high-temperature three-dimensional growth layer 12B, for example, to a thickness of 750 nm to 2000 nm. Within this range, the surface of the two-dimensional growth layer 13 can be sufficiently flattened. For example, the surface roughness RMS can be 0.5 nm to 5 nm. The thickness is more preferably 1000 nm to 1750 nm, and still more preferably 1250 nm to 1500 nm.

The growth temperature of the two-dimensional growth layer 13 is preferably 1100° C. to 1200° C. When the temperature is within this range, the two-dimensional growth layer 13 can be sufficiently flattened. The growth temperature is more preferably 1120° C. to 1190° C., and still more preferably 1140° C. to 1180° C. The temperature may be the same as that in the step of forming the crystal nucleus layer 11 and the step of forming the high-temperature three-dimensional growth layer 12B.

The two-dimensional growth layer 13 has a growth rate equal to or larger than the growth rate of the high-temperature three-dimensional growth layer 12B and equal to or smaller than the growth rate of the crystal nucleus layer 11, which is preferably 5 nm/min to 50 nm/min. When the growth rate is within this range, the growth rate is sufficiently small, the change in tensile stress due to the flattening of the crystal can be relaxed, and the generation of cracks can be prevented. The growth rate is more preferably 10 nm/min to 40 nm/min, and still more preferably 15 nm/min to 30 nm/min.

The two-dimensional growth layer 13 has a V/III ratio equal to or smaller than the V/III ratio of the high-temperature three-dimensional growth layer 12B and equal to or larger than the V/III ratio of the crystal nucleus layer 11, which is preferably 50 to 500. The growth rate can be controlled within the above range. The V/III ratio is more preferably 100 to 400, and still more preferably 150 to 300.

A curvature of the wafer at the end of the growth of the two-dimensional growth layer 13 is preferably 50 km⁻¹ or more and 300 km⁻¹ or less. Here, the curvature is a positive value for recessed warpage and a negative value for protruded warpage. When the curvature of the wafer is within this range, cracks in the crystal layer can be further prevented. The curvature is more preferably 100 km⁻¹ or more and 200 km⁻¹ or less.

Through the above production step, it is possible to obtain a high-quality two-dimensional growth layer 13 that is flat, has few cracks, and has a small dislocation density. In particular, the high-quality two-dimensional growth layer 13 can be obtained at a temperature of 1250° C. or lower. Therefore, it is possible to use a general crystal growth apparatus using quartz as a component, and it is possible to reduce the apparatus cost and running cost.

After the two-dimensional growth layer 13 is formed, when the temperature is lowered to room temperature, a compressive stress is applied to the crystal layers up to the two-dimensional growth layer 13 due to the difference in linear expansion coefficient with the substrate 10, causing the wafer to warp in a protruded shape (see (d) in FIG. 3).

When switching between the periods T1 to T5, it is preferable to temporarily stop the supply of the raw material gas before changing the temperature, and then to supply the raw material gas again after changing the temperature to a predetermined temperature.

The crystal nucleus layer 11, the three-dimensional growth layer 12, and the two-dimensional growth layer 13 are grown under a reduced pressure. This is because the Al raw material gas has high reactivity, and the reactivity is reduced by reducing the pressure, thereby enabling a high-quality crystal to be obtained. In the first embodiment, the pressure is constant, but the pressure may be decreased as the growth temperature increases. A higher-quality crystal can be obtained.

### 2-7. Element Structure Forming Step

Next, the n-type layer 14, the active layer 15, the electron blocking layer 16, and the p-type layer 17 are laminated in this order on the two-dimensional growth layer 13 (see FIG. 5).

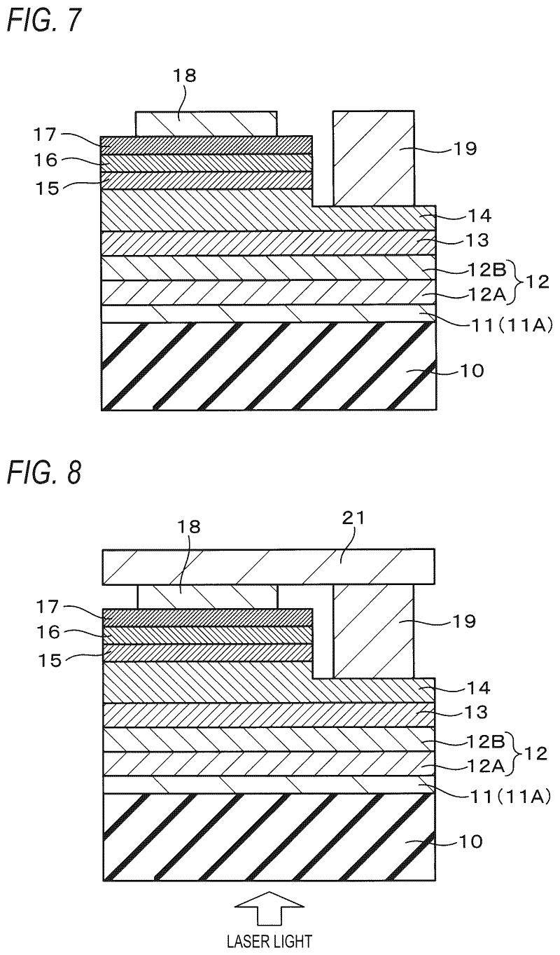

Next, a partial region of the p-type layer 17 is dry etched to form the groove reaching the n-type layer 14 (see FIG. 6). Then, the p-side electrode 18 is formed on the p-type layer 17, and the n-side electrode 19 is formed on the n-type layer 14 exposed on the bottom surface of the groove (see FIG. 7).

### 2-8. Void Forming Step

Next, the p-side electrode 18 and the n-side electrode 19 are bonded to the support substrate 21. Then, the back surface side of the substrate 10 is irradiated with laser light (see FIG. 8).

A wavelength of the laser light is set to a wavelength that allows passing through the substrate 10 and absorption by the crystal nucleus layer 11. The sapphire absorbs light having a wavelength of approximately 150 nm or less, and AlN absorbs light having a wavelength of approximately 220 nm or less. Therefore, the wavelength is preferably set to be larger than 150 nm and 220 nm or less. For example, an ArF excimer laser having a wavelength of 193 nm can be used.

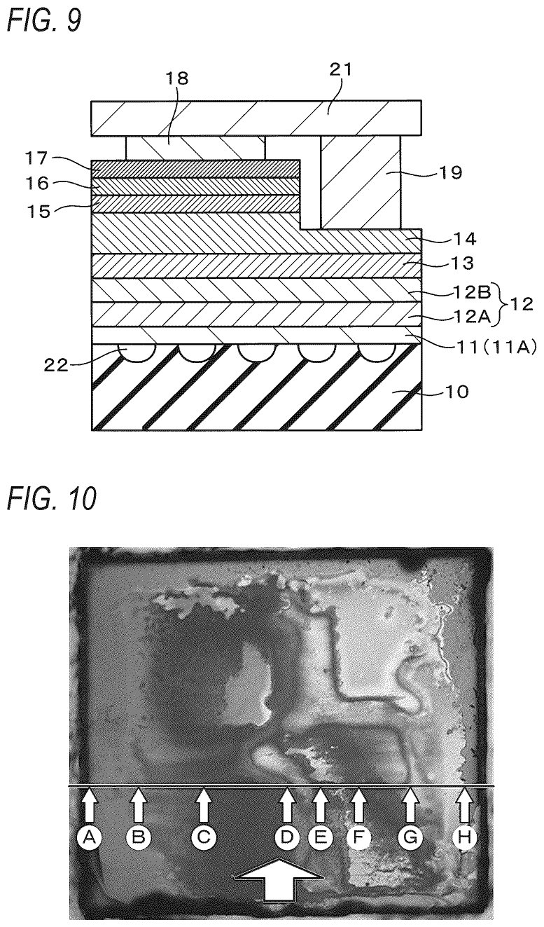

When the back surface side of the substrate 10 is irradiated with laser light having such a wavelength and a predetermined energy density, a plurality of voids 22 are formed on the substrate 10 side near the interface between the substrate 10 and the crystal nucleus layer 11 (see FIG. 9). When the voids 22 are spatially continuous with the outside of the element, the voids 22 are filled with air. When the voids 22 are not spatially continuous with the outside of the element, the inside of the voids 22 is thought to be filled with oxygen. The plurality of voids 22 may be formed discretely, or adjacent voids 22 may overlap and be continuous with each other. Increasing the overlap of the voids 22 makes it easier to separate the substrate 10. The shape, the width, the height, and the interval of the voids 22 can be controlled based on the energy density of the laser light. A cross-sectional shape of the void 22 may be elliptical, circular, rectangular, or the like. For example, the void 22 has a width of 0.02 μm to 1 μm, the void 22 has a height of 0.01 μm to 1 μm, and the interval between the voids 22 is 1 μm or less.

The energy density of the laser light may be any value as long as it is high enough to sufficiently heat the crystal nucleus layer 11 and decompose the substrate 10 with the heat.

In laser lift-off in the conventional art, the substrate is separated by decomposing a buffer layer near the interface between the substrate 10 and the buffer layer. Therefore, when the buffer layer is made of AlN, the energy density of the laser light needs to be increased since an Al—N bond is strong.

In contrast, in the first embodiment, since the substrate 10 is decomposed, rather than the buffer layer (crystal nucleus layer 11) is decomposed, there is no need to break the Al—N bond, and the substrate 10 can be separated at a smaller energy density than in the conventional art.

For example, when the Al composition in the crystal nucleus layer 11 (a ratio of number of moles of Al in the crystal nucleus layer 11 to a total number of moles of the crystal nucleus layer 11) is x and the energy density (J/cm²) of the laser light is y, y≥3x−1.4 is satisfied. Accordingly, the voids 22 can be easily formed in the substrate 10, and the substrate 10 can be easily separated. In particular, when the energy density is 1.6 J/cm² or more, the voids 22 can be formed regardless of the Al composition.

In addition, the energy density of the laser light is preferably 5 J/cm² or less. Generally, the higher the energy density of the laser light, the more difficult it becomes to achieve, and damage to the crystal may occur. Since AlN has a thermal conductivity larger than that of the sapphire, it is thought that when the energy density is high, heat is easily transferred to the active layer 15, the p-side electrode 18, and the n-side electrode 19, causing damage. The energy density is more preferably 3 J/cm² or less.

A thickness of the substrate 10 is preferably 1000 μm or less, more preferably 500 μm or less, and most preferably 250 μm or less. Theoretically, the sapphire absorbs light at a wavelength of 150 nm or less, but actual sapphire produced as an industrial product contains small amounts of impurities and oxygen vacancies, which causes light absorption. Therefore, an intensity of the laser light gradually attenuates as it travels through the sapphire. Therefore, the thinner the substrate 10 is, the more the energy of the incident laser light can be directly absorbed by the crystal nucleus layer 11.

Reasons why the voids 22 are generated in the substrate 10 but not in the crystal nucleus layer 11 are presumed to be as follows. The emitted laser light passes through the substrate 10 made of sapphire without being absorbed, and is absorbed by the crystal nucleus layer 11 made of AlN. Therefore, the crystal nucleus layer 11 serves as a heat source. A region that generates the most heat is a region where the laser light is absorbed first, that is, the interface between the substrate 10 and the crystal nucleus layer 11. Here, the sapphire has a melting point lower than that of AlN. Therefore, it is thought that at the interface between the substrate 10 and the crystal nucleus layer 11, the substrate 10, which has a lower melting point, decomposes first. In addition, the sapphire has a thermal conductivity smaller than that of AlN and is less likely to dissipate heat. This difference in heat dissipation is thought to be one of the reasons why the voids 22 are generated in the substrate 10. It is thought that, due to the above mechanism, the voids 22 are not generated in the crystal nucleus layer 11.

The crystal nucleus layer 11 may be made of AlGaN to be described later, but the higher the Ga composition of the crystal nucleus layer 11, the lower the transmittance of the laser light. That is, the laser energy is absorbed at a smaller thickness. Therefore, it is thought that the higher the Ga composition, the larger the amount of heat generated at the interface between the substrate 10 and the crystal nucleus layer 11, and the more easily the substrate 10 decomposes.

### 2-9. Substrate Separation Step

Next, by applying a physical force, cracks are generated in the substrate 10 at positions where the voids 22 have been formed, and the substrate 10 is separated and removed from the crystal nucleus layer 11. Depending on a size of the void 22, the substrate 10 may be separated without the application of a physical force. At this time, the protrusion portion 20 is formed as a remaining portion of the substrate 10 on the back surface of the crystal nucleus layer 11. A planar pattern of the protrusion portions 20 is approximately the same as an inverted planar pattern of the voids 22.

The substrate 10 may be separated by allowing a solution capable of wet etching the crystal nucleus layer 11 to permeate the voids 22 and wet etching the crystal nucleus layer 11 near the interface between the substrate 10 and the crystal nucleus layer 11. For example, a solution such as TMAH or phosphoric acid can be used.

As described above, the light emitting element according to the first embodiment shown in FIG. 1 is produced.

### First Modification of First Embodiment

The nucleus 11A is not limited to AlN, but may be any Group III nitride semiconductor containing Al. For example, it may be AlGaN. In particular, AlGaN having an Al composition of 50% or more is preferred. When the Al composition is less than 50%, there is a possibility that the voids 22 may be generated on the crystal nucleus layer 11 side rather than the substrate 10 side during laser irradiation in the laser lift-off, but this can be prevented when the Al composition is 50% or more. The Al composition is more preferably 70% or more.

When AlGaN is used as the nucleus 11A, a difference in lattice constant with the substrate 10 made of sapphire is increased, and the strain relaxation at the interface between the substrate 10 and the nucleus 11A is increased. In addition, when the nucleus 11A is made of AlGaN, the low-temperature three-dimensional growth layer 12A formed thereon has an Al composition higher than that of the nucleus 11A, so that the low-temperature three-dimensional growth layer 12A growing on the nucleus 11A is subjected to a tensile strain. This is because the growing crystals form in a manner of matching the lattice constant of the layer below the crystals. Therefore, this can relax the compressive strain generated in the low-temperature three-dimensional growth layer 12A and subsequent layers due to a thermal stress in the substrate and the crystal layer generated when the growth is completed and the temperature is room temperature.

In addition, due to the strain relaxation at the interface between the substrate 10 and the nuclei 11A, the nuclei 11A are formed discretely rather than in a film shape, so that the generation of cracks is prevented. In addition, the low-temperature three-dimensional growth layer 12A formed on the crystal nucleus layer 11 receives the tensile stress from the crystal nucleus layer 11 due to the difference in lattice constant, but the generation of cracks due to the tensile stress is prevented due to the three-dimensional growth. As a result of the above, the threading dislocation density of the two-dimensional growth layer 13 can be reduced.

In addition, when the nucleus 11A is made of AlGaN, the surfactant effect of Ga allows the nucleus 11A to be enlarged, and the nucleus density can be reduced. As described above, a small nucleus density can reduce the tensile stress generated on the surface when the nuclei are combined into a flat film. In addition, the number of combining surfaces where the nuclei 11A are combined is reduced, the formation of the threading dislocations can be reduced, and a high-quality crystal film can be formed.

When the nucleus 11A is made of AlGaN, the size of the nucleus 11A is preferably 20 nm to 100 nm. When the size of the nucleus 11A is within this range, the tensile stress can be sufficiently reduced. In addition, the variation in size of the nucleus 11A (the difference between the maximum diameter and the average diameter, and the difference between the average diameter and the minimum diameter) is preferably 20 nm or less.

In addition, when the nucleus 11A is made of AlGaN, the thickness of the crystal nucleus layer 11 is preferably 5 nm to 100 nm. Since the nucleus 11A is larger than in the case where AlN is used as the nucleus 11A, the crystal nucleus layer 11 also becomes thicker. As a result of the nucleus 11A being larger, the quality of the crystal layer formed after the nucleus 11A can be further improved. The thickness of the crystal nucleus layer 11 is more preferably 5 nm to 50 nm. When the nucleus 11A is made of AlGaN and has high Ga composition, the crystal is more mobile by annealing, and it is easier to enlarge the nucleus 11A by solid phase growth. With the annealing, the size of the nucleus 11A immediately before the three-dimensional growth layer is grown can be increased to reduce the density.

In addition, when the nucleus 11A is made of AlGaN, the density of the nucleus 11A is preferably 3×10¹¹/cm⁻² or less. Since the nucleus 11A is larger than in the case of AlN, the density of the nucleus 11A is also smaller than in the case of AlN. The density is more preferably 1.5×10¹¹/cm⁻² or less, and more preferably 1×10¹¹/cm⁻² or less. In addition, when the nucleus 11A is made of AlGaN, the nucleus 11A can be enlarged by annealing. That is, the nucleus density can be 1×10¹¹/cm⁻² or less.

In addition, in the first embodiment, the low-temperature three-dimensional growth layer 12A is made of AlN, but is not limited to AlN and may be made of AlGaN. However, in terms of strain relaxation and crystallinity, a difference between the Al composition in the low-temperature three-dimensional growth layer 12A and the Al composition in the crystal nucleus layer 11 is preferably 40% or less.

In addition, in the first embodiment, the high-temperature three-dimensional growth layer 12B is made of AlN, but is not limited to AlN and may be made of AlGaN. However, in terms of strain relaxation and crystallinity, a difference between the Al composition in the high-temperature three-dimensional growth layer 12B and the Al composition in the low-temperature three-dimensional growth layer 12A is preferably 30% or less.

In addition, in the first embodiment, the two-dimensional growth layer 13 is made of AlN, but is not limited to AlN and may be made of AlGaN. However, in terms of strain relaxation and crystallinity, a difference between the Al composition in the two-dimensional growth layer 13 and the Al composition in the high-temperature three-dimensional growth layer 12B is preferably 20% or less.

In addition, when a device to be formed on the two-dimensional growth layer 13 is a light emitting device, crystal layers below the two-dimensional growth layer 13 need to have an Al composition at which no light is absorbed. When the device to be formed on the two-dimensional growth layer 13 is an ultraviolet emitting LED, the Al composition in the two-dimensional growth layer 13 is preferably equal to or higher than the Al composition in an n-type layer of the LED.

For the above reasons, most of the device structure is often formed with an Al composition smaller than the Al composition in the two-dimensional growth layer 13. In order to relax the strain of the device structure, it is preferable to change the difference in lattice mismatch stepwise. It is preferable that the Al compositions in the three-dimensional growth layer 12 and subsequent layers, excluding the crystal nucleus layer 11, decrease stepwise. In this way, the strain applied to the device structure can be relaxed.

When the Al composition of the nucleus 11A decreases, the lattice constant changes from AlN to that of GaN. That is, the in-plane lattice constant is increased. Therefore, the three-dimensional growth layer 12 formed on the nucleus 11A and having an Al composition higher than that the Al composition of the nucleus 11A receives the tensile strain from the nucleus 11A. When the Al composition of the nucleus 11A decreases, the in-plane lattice constant of the three-dimensional growth layer 12 tends to be increased. When the growing three-dimensional growth layer 12 receives the tensile strain, the possibility of crack formation increases, so that there is an optimum value for the difference in Al composition between the nucleus 11A and the three-dimensional growth layer 12, as described above. When the growth is completed and the temperature is room temperature, the tensile strain formed in the three-dimensional growth layer 12 and subsequent layers during growth becomes a compressive strain due to the difference in thermal expansion coefficient with the substrate 10 made of sapphire. However, similar to the growth, as the lattice constant of the nucleus 11A increases, the compressive strain generated in the three-dimensional growth layer 12 and subsequent layers at room temperature is relaxed.

In addition, when the nucleus 11A is made of AlGaN, the thickness of the two-dimensional growth layer 13 is preferably 0.5 μm to 5 μm. The surface of the two-dimensional growth layer 13 can be sufficiently flattened. For example, the surface roughness RMS can be 0.5 nm to 5 nm. The thickness of the two-dimensional growth layer 13 is more preferably 1 μm to 3 μm.

In addition, when the nucleus 11A is made of AlGaN, the threading dislocation density of the two-dimensional growth layer 13 can be 5×10¹¹ cm⁻² or less, and a good-quality crystal can be obtained. In addition, in rocking curve measurement in X-ray diffraction of the two-dimensional growth layer 13, the full width at half maximum (FWHM) of the (002) diffraction line can be, for example, 100 arcsec to 300 arcsec, and the full width at half maximum of the (102) diffraction line can be, for example, 300 arcsec to 600 arcsec. This is because the full width at half maximum can be sufficiently reduced by reducing the threading dislocation density.

### Other Modifications of First Embodiment

In the first embodiment, the n-side electrode 19 is provided on the same side as the p-side electrode 18. Alternatively, after the laser lift-off, the crystal nucleus layer 11 can be etched to expose the n-type layer 14, and the n-side electrode 19 can be provided on the exposed n-type layer 14, thereby implementing a light emitting element having a vertical structure (a structure that provides electrical conductivity in a direction perpendicular to the main surface of the semiconductor layer). In addition, when the crystal nucleus layer 11, the three-dimensional growth layer 12, and the two-dimensional growth layer 13 are made into an n-type, the n-side electrode 19 can be formed on the back surface of the crystal nucleus layer 11 to implement a light emitting element having a vertical structure.

The first embodiment is directed to a light emitting element, but the present invention is not limited to a light emitting element and can be applied to any semiconductor element. In addition, the process can be completed after the two-dimensional growth layer 13 is grown, and the substrate can be used as a template substrate.

As shown in FIG. 15, the surface exposed by the separation of the substrate 10 may be etched to form large unevenness having a depth from the crystal nucleus layer 11 to the low-temperature three-dimensional growth layer 12A and the high-temperature three-dimensional growth layer 12B. A light scattering effect can be further improved. At this time, the protrusion portion 20 may remain or may disappear completely. The unevenness may be random unevenness as shown in FIG. 15, or may be a periodic unevenness structure. In addition, it is preferable that the period of unevenness is larger than the wavelength of the ultraviolet light emitted from the active layer 15.

The formation of the void 22 and the separation of the substrate 10 may be performed not only after dividing into elements, but also in the wafer state. Here, the wafer may be in the state shown in FIG. 5 after the crystal growth step is completed, or may be in the state after electrodes are formed and before element separation.

In the case of bonding to the support substrate 21 as shown in FIG. 1, a gap is generated between the p-side electrode 18 and the support substrate 21, and between the n-side electrode 19 and the support substrate 21. The gap is unsupported and therefore has low mechanical strength. Therefore, in order to increase the strength of this region, an underfill such as a resin (liquid curable resin) may be inserted into the gap.

The light emitting element in the first embodiment may be sealed with a fluororesin film or a quartz lens. In this case, a space between the crystal nucleus layer 11 side of the light emitting element and the fluororesin film, or between the crystal nucleus layer 11 side and the quartz lens, may be filled with a fluorocarbon compound. By reducing a difference in refractive index, the light extraction efficiency can be improved.

The thicknesses of the electron blocking layer 16 and the p-type layer 17 are preferably set such that ultraviolet light from the active layer 15 toward the substrate 10 and light from the active layer 15 toward the p-side electrode 18 and reflected by the p-side electrode 18 toward the substrate 10 are reinforced by interference.

### 3. Experiment Results

Next, various experiment results according to the first embodiment will be described.

### Experiment 1

A 1 mm square element structure was prepared by the method for producing a light emitting element according to the first embodiment, and then the substrate 10 side was irradiated with laser light. The crystal nucleus layer 11 had an Al composition of 79% and a thickness of 50 nm.

The support substrate 21 was a ceramic substrate made of AlN. An ArF excimer laser was used as the laser light, and the energy density was set to 1.5 J/cm².

An area in which voids can be formed by laser irradiation tends to increase as the laser energy density increases, but when the laser energy density is 1.5 J/cm² or more, the voids can be formed in an area of approximately 0.5 mm×0.5 mm. Therefore, in order to form voids over an entire 1 mm square, irradiation was performed on each of four divided regions.

This irradiation on four divided regions resulted in an overlapping region of the laser light irradiation region near the center. Since the laser energy is weaker towards the outer periphery of the spot, the size of the voids formed tends to be smaller. Therefore, it is expected that the irradiation energy is insufficient on the outer periphery of the element.

FIG. 10 is a photograph of a sample viewed from the substrate 10 side. The sample was cut along a dotted line in FIG. 10, and cross-sectional SEM images of a region near the interface between the substrate 10 and the crystal nucleus layer 11 at positions A to H in FIG. 10 were obtained.

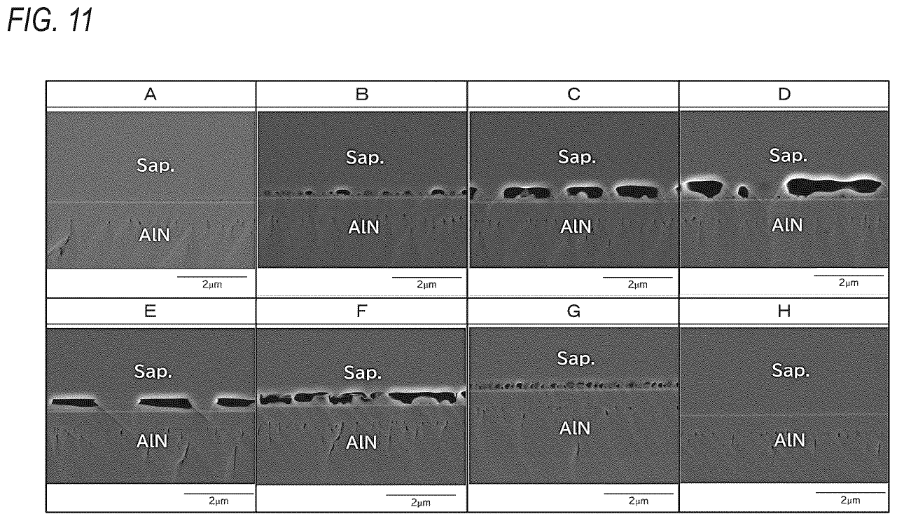

FIG. 11 shows the obtained cross-sectional SEM images. As shown in FIG. 11, at the positions A to G, the voids 22 were formed in a region in the sapphire as the interface between the sapphire substrate 10 and the crystal nucleus layer 11. In addition, the voids 22 were large near the center of the sample, i.e., in the regions where the laser irradiation overlaps (D and E), and near the center of the laser (C and F), and the voids 22 were smaller toward the outer periphery (B and G). From this, it is seen that the stronger the irradiation intensity of the laser light, the larger the voids 22 are, and it is seen that the size of the voids 22 can be controlled. In the regions (A and H) corresponding to the outer periphery of the laser spot, the voids 22 were extremely small or could not be identified.

From the above, in the case of actually peeling off the substrate 10, the laser irradiation energy, the number of times of laser irradiation, and the laser irradiation method are adjusted so as to form uniform voids over the entire element. Note that, for the sample in FIG. 10, the selected conditions did not cause peeling off of the substrate 10 for the cross-sectional evaluation.

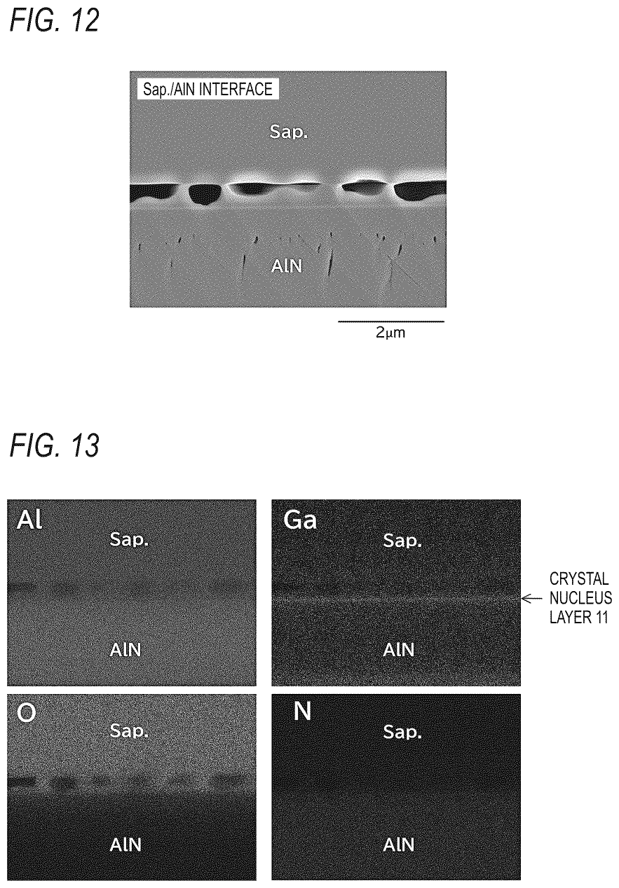

In addition, on the region of the SEM image shown in FIG. 12, EDS analysis was performed and elemental analysis of Al, Ga, O, and N was performed. FIG. 13 is a diagram showing element mapping. As seen from the results in FIG. 13, Ga is distributed in a thin layer, and since only the crystal nucleus layer 11 contains Ga in the region of the SEM image, the crystal nucleus layer 11 remains between the substrate 10 (sapphire) and the low-temperature three-dimensional growth layer 12A (AlN). It is also seen that the voids 22 are formed on the substrate 10 side, and not formed in the crystal nucleus layer 11. It is further seen that the low-temperature three-dimensional growth layer 12A is not damaged by the irradiation with laser light.

### Experiment 2

Three types of samples were prepared in the same manner as in Experiment 1, with the crystal nucleus layer 11 being made of AlN, AlGaN having an Al composition of 89%, and AlGaN having an Al composition of 79%. The energy density of the laser light was set to two values, 1.5 J/cm² and 1.7 J/cm², when the crystal nucleus layer 11 was made of AlN and AlGaN having an Al composition of 89%, and to two values, 1.3 J/cm² and 1.5 J/cm², when the crystal nucleus layer 11 was made of AlGaN having an Al composition of 79%. Then, a predetermined force was applied to the substrate 10 of each sample, and it was checked whether the substrate 10 was separated.

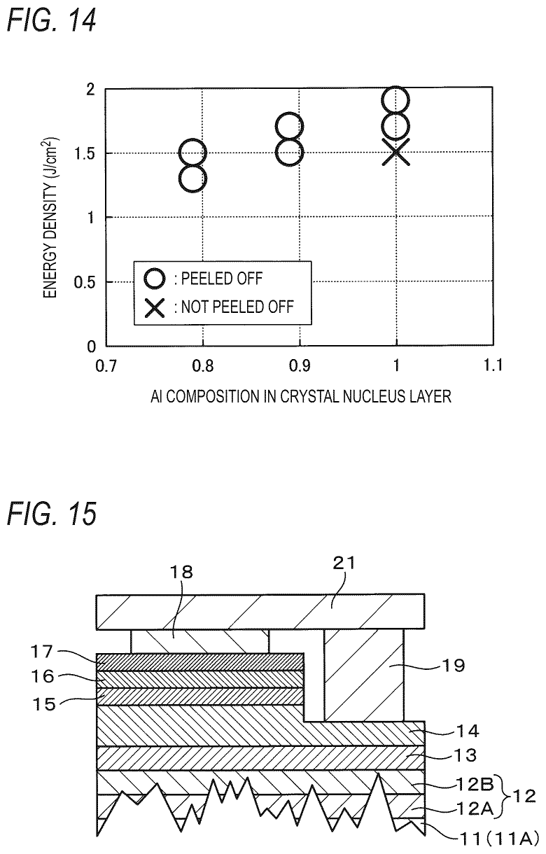

FIG. 14 is a graph showing a relationship between the Al composition of the crystal nucleus layer 11, the energy density (J/cm²) of the laser light, and the presence or absence of peeling off of the substrate 10. As seen from FIG. 14, the lower the Al composition, the smaller the energy density of the laser light required to peel off the substrate 10 is. This is presumably because, as the Al composition decreases, the physical properties become closer to those of GaN, making it easier to absorb the laser light, and the amount of heat generated at the interface between the substrate 10 and the crystal nucleus layer 11 increases, making it easier for the voids 22 to form. In addition, it is thought that, when the Al composition is too low, the absorption of the laser light in the crystal nucleus layer 11 is too large, causing the crystal nucleus layer 11 to reach the decomposition temperature, resulting in the formation of the voids 22 in the crystal nucleus layer 11. In order to prevent this, it is presumed that the Al composition of the crystal nucleus layer 11 needs to be 50% or more.

Further, it is presumed from FIG. 14 that the substrate 10 can be separated when y≥3x−1.4 is satisfied, where x is the Al composition of the crystal nucleus layer 11 and y is the energy density (J/cm²) of the laser light.

### REFERENCE SIGNS LIST

10: substrate
11: crystal nucleus layer
12: three-dimensional growth layer
12A: low-temperature three-dimensional growth layer
12B: high-temperature three-dimensional growth layer
13: two-dimensional growth layer
14: n-type layer
15: active layer
16: electron blocking layer
17: p-type layer
18: p-side electrode
19: n-side electrode
20: protrusion portion
21: support substrate
22: void

What is claimed is:

1. A method for producing a Group III nitride semiconductor comprising:
forming a crystal nucleus layer by generating nuclei of AlGaN or AlN over a substrate comprising sapphire;
forming a semiconductor layer comprising a Group III nitride semiconductor over the crystal nucleus layer;
forming a void by irradiating a back surface side of the substrate with laser light to pass the laser light through the substrate and cause the crystal nucleus layer to absorb the laser light to thereby generate heat in the crystal nucleus layer, and by conducting the heat from the crystal nucleus layer to the substrate to decompose a region of the substrate near an interface with the crystal nucleus layer; and
separating the substrate from the crystal nucleus layer at a position of the void.

2. The method for producing a Group III nitride semiconductor according to claim 1, wherein in the separating of the substrate, a protrusion portion is formed on a surface of the crystal nucleus layer facing the substrate by a part of the substrate remaining on the crystal nucleus layer.

3. The method for producing a Group III nitride semiconductor according to claim 1, which satisfies the following formula:
y≥3x−1.4
wherein x represents a ratio of number of moles of Al in the crystal nucleus layer to a total number of moles of the crystal nucleus layer, and y represents an energy density (J/cm²) of the laser light.

4. The method for producing a Group III nitride semiconductor according to claim 1, wherein the laser light has an energy density of 1.6 J/cm² or more.

5. The method for producing a Group III nitride semiconductor according to claim 3, wherein the energy density of the laser light is 5 J/cm² or less.

6. The method for producing a Group III nitride semiconductor according to claim 1, wherein the nuclei of the crystal nucleus layer are AlGaN or AlN having an Al composition of 50 mol % or more.

7. The method for producing a Group III nitride semiconductor according to claim 1, wherein
the semiconductor layer comprises a low-temperature three-dimensional growth layer provided over the crystal nucleus layer, and a high-temperature three-dimensional growth layer provided over the low-temperature three-dimensional growth layer, and
the forming of the semiconductor layer comprises:
forming the low-temperature three-dimensional growth layer by growing AlGaN or AlN from the nuclei at a temperature lower than a temperature in the forming of the crystal nucleus layer and combining crystals from adjacent ones of the nuclei; and
forming the high-temperature three-dimensional growth layer by growing AlGaN or AlN from the low-temperature three-dimensional growth layer at a temperature higher than the temperature in the forming of the low-temperature three-dimensional growth layer and equal to or lower than the temperature in the forming of the crystal nucleus layer.

8. The method for producing a Group III nitride semiconductor according to claim 7, wherein
the temperature in the forming of the crystal nucleus layer is 1100° C. or higher and 1200° C. or lower,
the temperature in the forming of the low-temperature three-dimensional growth layer is 900° C. or higher and 1100° C. or lower, and
the temperature in the forming of the high-temperature three-dimensional growth layer is 1050° C. or higher and 1200° C. or lower.

9. The method for producing a Group III nitride semiconductor according to claim 1, wherein
the semiconductor layer comprises a low-temperature three-dimensional growth layer provided over the crystal nucleus layer, and a high-temperature three-dimensional growth layer provided over the low-temperature three-dimensional growth layer, and
the forming of the semiconductor layer comprises:
forming the low-temperature three-dimensional growth layer by growing AlGaN or AlN from the nuclei at a growth rate slower than a growth rate of the crystal nucleus layer and combining crystals from adjacent ones of the nuclei, and
forming the high-temperature three-dimensional growth layer by growing AlGaN or AlN from the low-temperature three-dimensional growth layer at a growth rate faster than the growth rate of the low-temperature three-dimensional growth layer and equal to or slower than the growth rate of the crystal nucleus layer.

10. The method for producing a Group III nitride semiconductor according to claim 9, wherein
the growth rate of the crystal nucleus layer is 5 nm/min or more and 100 nm/min or less,
the growth rate of the low-temperature three-dimensional growth layer is 2 nm/min or more and 20 nm/min or less, and
the growth rate of the high-temperature three-dimensional growth layer is 5 nm/min or more and 50 nm/min or less.

11. The method for producing a Group III nitride semiconductor according to claim 1, further comprising, after the separating of the substrate:
forming unevenness having a depth from the crystal nucleus layer to the semiconductor layer by etching a side of the crystal nucleus layer exposed by the separating of the substrate.

12. The method for producing a Group III nitride semiconductor according to claim 2, further comprising, after the separating of the substrate:
forming unevenness having a depth from the crystal nucleus layer to the semiconductor layer by etching a side of the crystal nucleus layer exposed by the separating of the substrate.

13. The method for producing a Group III nitride semiconductor according to claim 1, further comprising, before the forming of the crystal nucleus layer:
subjecting the substrate to a heat treatment under a hydrogen-dominated atmosphere at a temperature higher than a temperature in the forming of the crystal nucleus layer.

14. A Group III nitride semiconductor comprising:
a crystal nucleus layer, which is a layer in which nuclei of AlGaN or AlN are generated and grown;
a semiconductor layer containing a Group III nitride semiconductor, which is provided on one surface of the crystal nucleus layer; and
a plurality of protrusion portions made from sapphire, which are provided on other surface of the crystal nucleus layer, wherein
the other surface of the crystal nucleus layer is exposed between adjacent ones of the plurality of protrusion portions.

15. The Group III nitride semiconductor according to claim 14, wherein each of the plurality of protrusion portions has a height of 0.01 μm to 1 μm, each of the plurality of protrusion portions has a width of 0.01 μm to 1 μm, and adjacent ones of the plurality of protrusion portions has a center-to-center distance of 0.02 μm to 5 μm.

16. The Group III nitride semiconductor according to claim 14, wherein the semiconductor layer comprises:
a three-dimensional growth layer provided on the crystal nucleus layer, which is a layer in which AlGaN or AlN is grown from the nuclei and crystals from adjacent ones of the nuclei are combined, and
a two-dimensional growth layer provided on the three-dimensional growth layer, which is a layer in which AlGaN or Ga-doped AlN is grown from the three-dimensional growth layer.

17. The Group III nitride semiconductor according to claim 15, wherein the semiconductor layer comprises:
a three-dimensional growth layer provided on the crystal nucleus layer, which is a layer in which AlGaN or AlN is grown from the nuclei and crystals from adjacent ones of the nuclei are combined, and
a two-dimensional growth layer provided on the three-dimensional growth layer, which is a layer in which AlGaN or Ga-doped AlN is grown from the three-dimensional growth layer.
